(19) United States
(12) Patent Application Publication
(10) Pub. No.: US 2026/0107428 A1
(43) Pub. Date: Apr. 16, 2026

(54) Layout pattern of static random access memory and manufacturing method thereof

(71) Applicant: UNITED MICROELECTRONICS CORP., Hsin-Chu City (TW)

(72) Inventors: Li-Hsuan Ho, Kaohsiung City (TW); Liang-Wei Chiu, Tainan City (TW); Tsung-Hsun Wu, Kaohsiung City (TW); Chun-Yen Tseng, Tainan City (TW); Shu-Ru Wang, Taichung City (TW); Yu-Tse Kuo, Tainan City (TW)

(73) Assignee: UNITED MICROELECTRONICS CORP., Hsin-Chu City (TW)

(21) Appl. No.: 18/946,932

(22) Filed: Nov. 14, 2024

(30) Foreign Application Priority Data
Oct. 14, 2024 (TW) 113138902

(51) Int. Cl. H10B 10/00

(52) U.S. Cl. CPC H10B 10/12

(57) ABSTRACT

The invention provides a layout pattern of a static random access memory, which comprises a first region adjacent to a second region, a first SRAM cell located in the first region, a first diffusion region in the first region, and a second SRAM cell located in the second region, which comprises a second diffusion region. A gate structure spans the first diffusion region and constitutes a first pass gate transistor of the first SRAM cell, and the gate structure spans the second diffusion region and constitutes a second pass gate transistor of the second SRAM cell, wherein the gate structure extends along a first direction, and the first diffusion region overlapping with the gate structure and the second diffusion region overlapping with the gate structure are not connected in the first direction.

### BACKGROUND OF THE INVENTION

### 1. Field of the Invention

The invention relates to a layout pattern of static random access memory, in particular to a layout pattern of static random access memory for reducing leakage current between adjacent regions.

### 2. Description of the Prior Art

An embedded static random access memory (embedded SRAM) includes a logic circuit and a static random access memory connected with the logic circuit. Static random access memory itself belongs to a volatile memory cell, that is, when the power supplied to static random access memory disappears, the stored data will be erased at the same time. Static random access memory (SRAM) stores data by using the conductive state of the transistors in the memory cell. The design of SRAM is based on mutually coupled transistors, which has no problem of capacitor discharge, and does not need to be continuously charged to keep the data from losing, that is, it does not need to update the memory, which is different from the Dynamic Random Access Memory, DRAM) which belongs to the volatile memory, which uses the charged state of the capacitor to store data. The access speed of static random access memory is quite fast, so it has applications as cache memory in computer systems.

### SUMMARY OF THE INVENTION

The invention provides a layout pattern of a static random access memory, which comprises a first region and a second region, wherein the first region and the second region are adjacent to each other, a first SRAM cell located in the first region, which contains a first diffusion region, a second SRAM cell located in the second region, which contains a second diffusion region, a gate structure spanning the first region and the second region, wherein the gate structure spans the first diffusion region and constitutes a first pass gate transistor of the first SRAM cell, and the gate structure spans the second diffusion region and constitutes a second pass gate transistor of the second SRAM cell, wherein the gate structure extends along a first direction, and the first diffusion region overlapping with the gate structure and the second diffusion region overlapping with the gate structure are not connected in the first direction.

The invention also provides a manufacturing method of layout pattern of static random access memory, which includes defining a first region adjacent to a second region, forming a first SRAM cell in the first region, wherein the first region contains a first diffusion region, forming a second SRAM cell in the second region, and the second region contains a second diffusion region, forming a gate structure spanning the first region and the second region, wherein the gate structure spans the first diffusion region and constitutes a first pass gate transistor of the first SRAM cell, and the gate structure spans the second diffusion region and constitutes a second pass gate transistor of the second SRAM cell, wherein the gate structure extends along a first direction, and the first diffusion region overlapping with the gate structure and the second diffusion region overlapping with the gate structure are not connected in the first direction.

The present invention discloses a layout pattern of 6T-SRAM. When a plurality of SRAM cells are arranged adjacent to each other, some components may be shared, but at the same time, larger leakage current may be generated. The invention is characterized in that the diffusion region of the second pass gate transistor in the first region and the diffusion region of the second pass gate transistor in the adjacent second region are designed to be separated from each other, but the gate structure of the second pass gate transistor in the first region and the gate structure of the second pass gate transistor in the adjacent second region are still in contact with each other. When the word line is turned on, electrons will flow into the diffusion region below the gate structure, but since the diffusion regions below the gate structure are not connected with each other, so the leakage current between the two regions can be effectively isolated, and the quality of the SRAM can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a circuit diagram of a six transistor SRAM (6T-SRAM) cell of the present invention.

FIG. 2 is a layout diagram of 6T-SRAM according to an embodiment of the present invention.

FIGS. 3 to 4 are schematic cross-sectional views of a second pass gate transistor PG2 fabricated along the direction of the tangent line AA′ in FIG. 2 according to an embodiment of the present invention.

FIG. 5 shows a layout pattern of a static random access memory (SRAM) according to a second embodiment of the present invention.

FIG. 6 shows a layout pattern of a static random access memory (SRAM) according to a third embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

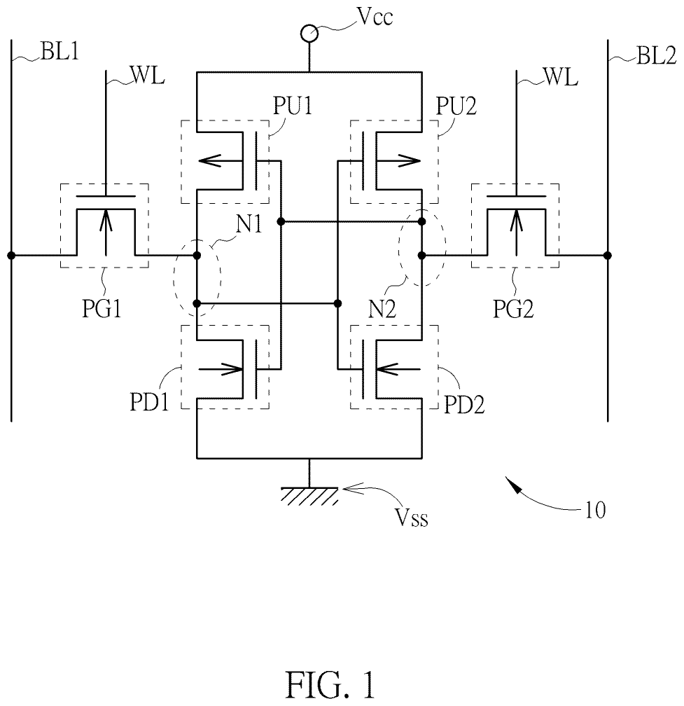

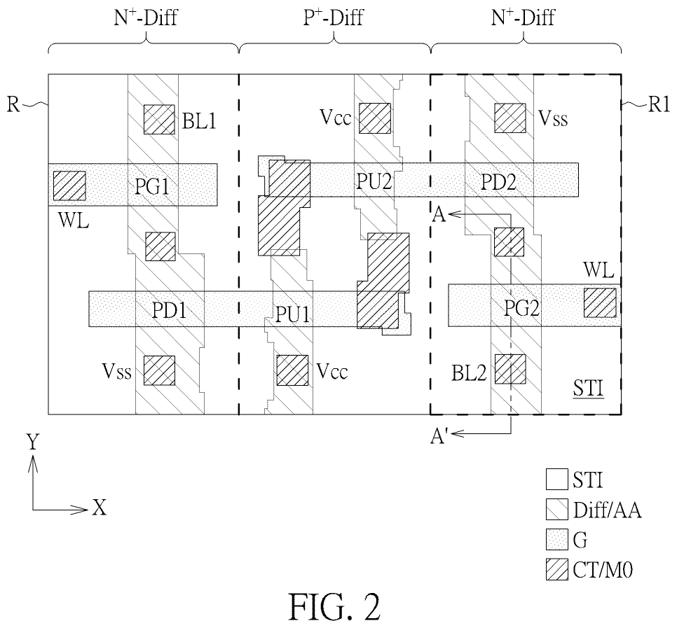

Referring to FIGS. 1-2, FIG. 1 illustrates a circuit diagram of a six-transistor SRAM (6T-SRAM) cell of a SRAM of the present invention and FIG. 2 illustrates a layout of the 6T-SRAM according to an embodiment of the present invention. As shown in FIGS. 1-2, the SRAM device of the present invention preferably includes at least one SRAM cell, each SRAM cell including a six-transistor SRAM (6T-SRAM) cell 10.

In this embodiment, each 6T-SRAM cell 10 is composed of a first pull-up transistor PU1, a second pull-up transistor PU2, a first pull-down transistor PD1, a second pull-down transistor PD2, a first pass gate transistor PG1 and a second pass gate transistor PG2. These six transistors constitute a set of flip-flops. The first and the second pull-up transistors PU1 and PU2, and the first and the second pull-down transistors PD1 and PD2 constitute a latch that stores data in the storage nodes N1 and N2. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source Vcc, the first and the second pull-down transistors PD1 and PD2 share a source/drain region and electrically connect to a voltage source Vss.

Preferably, the first and the second pull-up transistors PU1 and PU2 of the 6T-SRAM cell 10 are composed of p-type metal oxide semiconductor (PMOS) transistors; the first and the second pull-down transistors PD1 and PD2, and first and the second pass gate transistors PG1 and PG2 are composed of n-type metal oxide semiconductor (NMOS) transistors. The first pull-up transistor PU1 and the first pull-down transistor PD1 constitute an inverter, which further form a series circuit. One end of the series circuit is connected to a voltage source Vcc and the other end of the series circuit is connected to a voltage source Vss. Similarly, the second pull-up transistor PU2 and the second pull-down transistor PD2 constitute another inverter and a series circuit. One end of the series circuit is connected to the voltage source Vcc and the other end of the series circuit is connected to the voltage source Vss.

The storage node N1 is connected to the respective gates of the second pull-down transistor PD2 and the second pull-up transistor PU2. The storage node N1 is also connected to the drains of the first pull-down transistor PD1, the first pull-up transistor PU1, and the first pass gate transistor PG1. Similarly, the storage node N2 is connected to the respective gates of the first pull-down transistor PD1 and first the pull-up transistor PU1. The storage node N2 is also connected to the drains of the second pull-down transistor PD2, the second pull-up transistor PU2, and the second access transistor PG2. The gates of the first and the second pass gate transistors PG1 and PG2 are respectively coupled to a word line (WL), and the sources are coupled to a relative data line (BL).

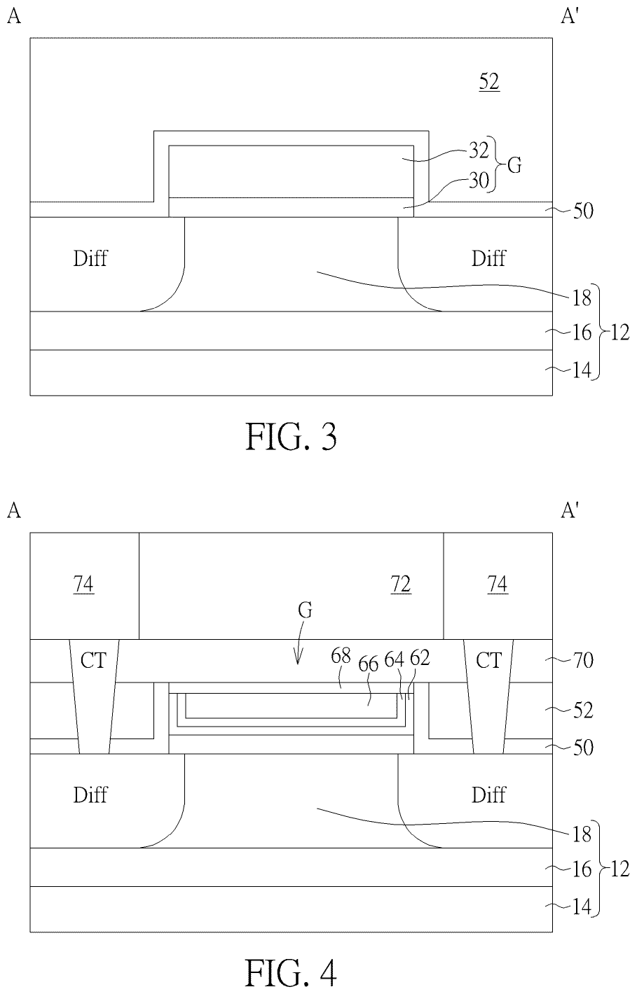

Please also refer to FIGS. 2 to 4. FIG. 2 shows the layout of SRAM cells in a first embodiment of the present invention, and FIGS. 3 to 4 are schematic cross-sectional views of the second pass gate transistor PG2 fabricated along the direction of the tangent line AA′ in FIG. 2. It is worth noting that the region R shown in FIG. 2 contains the smallest cell of a static random access memory (SRAM), while FIGS. 3 and 4 show the cross-sectional schematic diagram of the second pass gate transistor PG2 in the SRAM cell, and the method of manufacturing the second pass gate transistor PG2 will be explained in the following description paragraphs. It can be understood that, in addition to the second pass gate transistor PG2, each transistor in the SRAM cell described in the following embodiments can also be formed by the same method as illustrated in FIGS. 3 and 4, so the description will not be repeated here.

A shown in FIGS. 2 and 3, a substrate 12 made of silicon material such as a silicon-on-insulator (SOI) substrate is provided, in which the substrate 12 includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto.

It should be noted that even though the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, a plurality of active areas AA such as the regions marked by slanted lines in FIG. 2 are defined on the substrate 12, and then part of the second semiconductor layer 18 outside the active areas AA is removed to form a shallow trench isolation (STI) around the active areas AA or the remaining second semiconductor layer 18, in which an active device or radio frequency device is to be fabricated on the second semiconductor layer 18 surrounded by the STI in the later process.

Then, a plurality of gate structures G are formed on the substrate 12. Seen from the top view of the first pass gate transistor PG1, the gate structure G preferably extends on the substrate 12 along a first direction (for example, the X direction), and each gate structure is substantially elongated or strip shape. It should be noted that although the gate structure G of this embodiment takes a strip shape as an example, it is not limited to this. According to other embodiments of the present invention, the gate structure G can take on other shapes, such as an L-shape, and this variation is also within the scope of the present invention.

Preferably, the formation of the gate structure G could be accomplished by a gate first process, a high-k first approach from gate last process, or a high-k last approach from gate last process. Since this embodiment pertains to a high-k last approach, a gate dielectric layer 30 or interfacial layer made of silicon oxide, a gate material layer 32 preferably made of polysilicon, and a selective hard mask (not shown) could be formed sequentially on the substrate 12, and a pattern transfer process is then conducted by using a patterned resist (not shown) as mask to remove part of the gate material layer 32 and part of the gate dielectric layer 30 through single or multiple etching processes. After stripping the patterned resist, a gate structure G composed of a patterned gate dielectric layer 30 and patterned gate material layer 32 is formed on the substrate 12.

Next, at least a spacer (not shown) is formed on sidewalls of the gate structure G. In this embodiment, the spacer could be a single spacer or a composite spacer as the spacer could further include an offset spacer (not shown) and a main spacer (not shown). The offset spacer and the main spacer are preferably made of different materials while the offset spacer and main spacer could all be selected from the group consisting of SiO₂, SiN, SiON, and SiCN, but not limited thereto.

Then, an ion implantation process/doping step can be performed to dope different types of ions in different parts of the region R, so as to dope some active areas AA in the region R into diffusion regions Diff, and the diffusion regions Diff are used as the source/drain of each transistor. Specifically, a doping step is performed to form a doped region as a source/drain region in the substrate 12 or the active area AA on both sides of the gate structure G in the region R. Since the first pull-up transistor PU1 and the second pull-up transistor PU2 are PMOS transistors, the diffusion region Diff is doped with P-type ions, such as boron (B) ions. In addition, since the first pull-down transistor PD1, the second pull-down transistor PD2, the first pass gate transistor PG1 and the second pass gate transistor PG2 are NMOS transistors, the diffusion region Diff is doped with N-type ions, such as phosphorus (P) ions and arsenic (As) ions. In FIG. 2, N+-Diff denotes a diffusion region doped with N-type or N+ dopant, and P+-Diff denotes a diffusion region doped with P-type or P+ dopant. It is worth noting that after the doping step is completed, from the top view, the range of part of the active area AA overlaps with the diffusion region Diff (all the active areas AA not covered by the gate structure G are doped to become the diffusion region Diff), so they are represented by the same pattern.

Next, a selective salicide process could be conducted to form a silicide (not shown) on the surface of the diffusion regions Diff, a contact etch stop layer (CESL) 50 made of silicon nitride could be formed on the substrate 12 to cover the gate structure G, and then an inter-layer dielectric (ILD) layer 52 is formed on the CESL 50.

Next, as shown in FIG. 4, a planarizing process such as a chemical mechanical polishing (CMP) process is conducted to remove part of the ILD layer 52 and part of the CESL 50 so that the top surfaces of the gate structure G, the CESL 50, and ILD layer 52 are coplanar.

Next, a replacement metal gate (RMG) process is conducted to transform the gate structure G into metal gate. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 32 from gate structure G for forming a recess (not shown) in the ILD layer 52. Next, a high-k dielectric layer 62, a work function metal layer 64, and a low resistance metal layer 66 are formed in the recess, and a planarizing process such as CMP is conducted to remove part of low resistance metal layer 66, part of work function metal layer 64, and part of high-k dielectric layer 62 to form metal gate. In this embodiment, the gate structure G or metal gate fabricated through high-k last process of a gate last process preferably includes an interfacial layer or gate dielectric layer 30, a U-shaped high-k dielectric layer 62, a U-shaped work function metal layer 64, and a low resistance metal layer 66 as the high-k dielectric layer 62, the work function metal layer 64, and the low resistance metal layer 66 together serving as a gate electrode for each transistor or each device.

In this embodiment, the high-k dielectric layer 62 is preferably selected from dielectric materials having dielectric constant (k value) larger than 4. For instance, the high-k dielectric layer 62 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 64 is formed for tuning the work function of the metal gate in accordance with the conductivity of the device. For an NMOS transistor, the work function metal layer 64 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 64 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low-resistance metal layer 66 may include copper (Cu), aluminum (Al), titanium aluminum (TiAl), cobalt tungsten phosphide (CoWP) or any combination thereof. Because the techniques are well-known in this field to convert a dummy gate into a metal gate according to the metal gate replacement process, the details of which are not explained herein for the sake of brevity. Next, part of the high-k dielectric layer 62, part of the work function metal layer 64, and part of the low resistance metal layer 66 are removed to form a recess (not shown), and a hard mask 68 is then formed into the recess so that the top surfaces of the hard mask 68 and ILD layer 52 are coplanar. The hard mask 68 could be made of material including but not limited to for example SiO₂, SiN, SiON, SiCN, or combination thereof.

Next, a contact plug formation process could be conducted by forming another dielectric layer 70 on the ILD layer 52, conducting a photo-etching process by using a patterned mask (not shown) as mask to remove part of the dielectric layer 70 and part of the hard mask 68 directly on top of the gate structure G and part of the ILD layer 52 and part of the CESL 50 adjacent to the gate structure G for forming contact holes (not shown) exposing top surfaces of the gate structure G and the diffusion regions Diff. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs CT electrically connecting the gate structure G and the source/drain region (i.e., the diffusion region Diff). It is worth noting that the above contact plugs CT are mainly used to connect elements of different layers, but in some embodiments, the formed contact hole can also be used to connect elements of the same layer after being filled with metal material, for example, the gate of the second pull-up transistor PU2 and the drain of the first pull-up transistor PU1 are connected with each other, and the metal material layer at this layer can be defined as the 0th metal layer (M0), wherein both the 0th metal layer M0 and the contact plugs CT described here have the function of connecting different elements. Both of them preferably contain the same material, but are not limited to this. In addition, from the cross-sectional view in FIG. 4, the contact hole on the top surface of the gate structure G is not shown, but it can be understood that contact holes can be included in other parts of the gate structure G to facilitate the subsequent formation of contact plugs to electrically connect the gate structure G.

Next, a metal interconnective process could be conducted by first forming an inter-metal dielectric (IMD) layer 72 on the dielectric layer 70 and then conducting one or more photo-etching process to remove part of the IMD layer 72 for forming contact holes. Next, conductive materials are deposited into the contact hole and a planarizing process such as CMP is conducted to form a metal interconnections 74 directly contacting the contact plugs CT underneath. Similar to the contact plugs CT formed previously, each of the metal interconnections 74 could all be formed in the IMD layer 72 through single damascene or dual damascene process. For instance, each of the metal interconnections 74 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. This completes the fabrication of a semiconductor device according to an embodiment of the present invention.

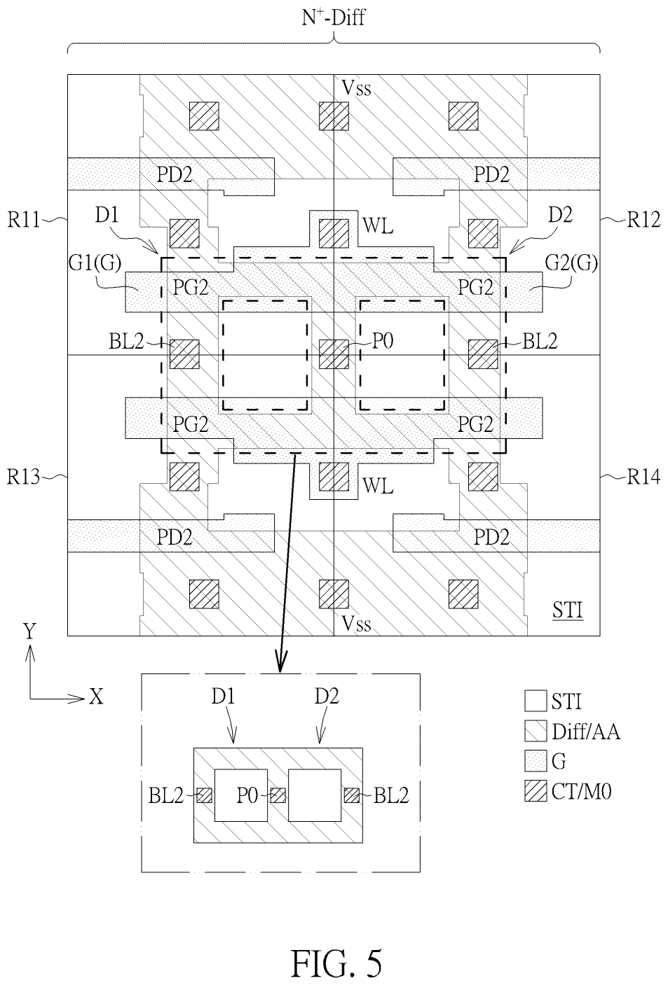

The layout pattern shown in FIG. 2 above is the layout pattern of the smallest SRAM cell, but in the actual electronic products, the layout pattern usually includes an array of many SRAM cells. When a plurality of SRAM cell patterns are arranged in an array, two adjacent SRAM cells may share a part of components with each other. For example, FIG. 5 shows a layout pattern of a static random access memory (SRAM) according to a second embodiment of the present invention. As shown in FIG. 5, it includes four adjacent regions R11, R12, R13 and R14, which are adjacent to each other, and each region R11-R14 includes an SRAM cell. In order to more clearly illustrate the characteristics of this embodiment, only a part of the SRAM cell patterns, such as the second pull-down transistor PD2 and the second pass gate transistor PG2, are drawn in each region R11-R14. Among them, the patterns in region R11 and region R12 are mirrored along the vertical direction, the patterns in region R11 and region R13 are mirrored along the horizontal direction, and the patterns in region R13 and region R14 are mirrored along the vertical direction. In addition, reference can be made to the region R1 shown in FIG. 2, in which the arrangement direction of the second pull-down transistor PD2 and the second pass gate transistor PG2 in the region R11 in FIG. 5 is similar to that in the region R1 shown in FIG. 2, so the positions of transistors not shown in FIG. 5 can also be known by referring to FIG. 2. It is worth noting that in FIG. 5, the first pull-up transistor PU1, the second pull-up transistor PU2, the first pull-down transistor PD1 and the first pass gate transistor PG1 are located outside the indicated range, so they are not drawn. However, it can be understood that these elements should exist in the SRAM pattern, and the layout and position of these elements can be shown with reference to FIG. 2, so they are not described in detail in this paragraph.

It is worth noting that when a plurality of SRAM cells are spliced with each other, a part of components can be shared to reduce the overall area of the semiconductor structure. For example, in FIG. 5, the diffusion regions Diff and the gate structures G among the SRAM cells in the regions R11-R14 can span different regions, and some of the contact plugs CT can be located between multiple regions, so that the SRAM cells in these adjacent regions can be connected to a same contact plug CT and the same signal source.

For example, in FIG. 5, the gate structure G of the second pass gate transistor PG2 located in the region R11 is defined as the gate structure G1, and the diffusion region Diff spanned by the gate structure G1 is defined as the diffusion region D1. In addition, the gate structure G of the second pass gate transistor PG2 located in the region R12 in FIG. 5 is defined as the gate structure G2, and the diffusion region Diff spanned by the gate structure G2 is defined as the diffusion region D2. As shown in FIG. 5, the gate structure G1 and the gate structure G2 are connected to each other and contacted with each other, and the diffusion regions D1 and D2 are also connected to each other and directly contacted with each other. In this way, the SRAM cells in the region R11 and the region R12 can share a part of components, such as the contact plug for connecting the word line WL (labeled as the contact plug CT next to WL in FIG. 5) or the contact plug for discharging excess accumulated charges (labeled as the pick-up contact plug P0 in FIG. 5). In addition, in order to clearly describe the connection relationship between the elements, some elements such as bit line WL, voltage source Vss, word line BL2, etc. are directly marked next to the contact structure CT of the layout pattern.

In this embodiment, in order to clearly describe the shapes of the diffusion regions D1 and D2, enlarged patterns of the diffusion regions D1 and D2 are drawn next to the layout patterns, wherein, from the top view, the diffusion regions D1 and D2 are, for example, frame-shaped composed of four strip patterns, and the diffusion regions D1 and D2 are connected to each other and share a strip pattern, for example, the strip pattern on the right side of the diffusion region D1 is shared with the strip pattern on the left side of the diffusion region D2, and the pick-up contact plug P0 is located on the right side of the diffusion region D1 (or the strip pattern on the left side of the diffusion region D2).

As shown in FIG. 5, taking the region R11 and the region R12 as examples, although the region R11 and the region R12 share a part of components, so that the area of the whole semiconductor structure can be reduced, but it also causes some problems, that is, the applicant finds that leakage current is more likely to occur between adjacent regions. More specifically, in the design of FIG. 5, the gate structure G1 and the gate structure G2 are connected with each other, and the connected gate structures G1 and G2 span the region R11 and the region R12. Similarly, the diffusion regions D1 and D2 are also connected to each other, and the connected diffusion regions D1 and D2 span the region R11 and the region R12. Therefore, when the voltage is applied to the word line WL (when the word line WL is turned on), the channels under the gate structures G1 and G2 are turned on, so electrons will flow into the diffusion regions D1 and D2 under the gate structures G1 and G2. Since diffusion regions D1 and D2 are connected to each other and span different regions, electrons flowing into diffusion regions D1 and D2 will easily generate leakage current and affect adjacent SRAM cells, especially after word line WL is turned on, the intensity of leakage current may obviously affect the operation of SRAM cells. Taking the applicant's experimental results as an example, the applicant measured the structure shown in FIG. 5, when the word line WL is not turned on, the measured leakage current intensity is about 10⁻¹⁴ A. However, after the word line WL is turned on, the measured leakage current intensity is obviously increased to about 10⁻⁷ A, which is enough to affect the operation of SRAM cells and further affect the quality of the whole semiconductor device.

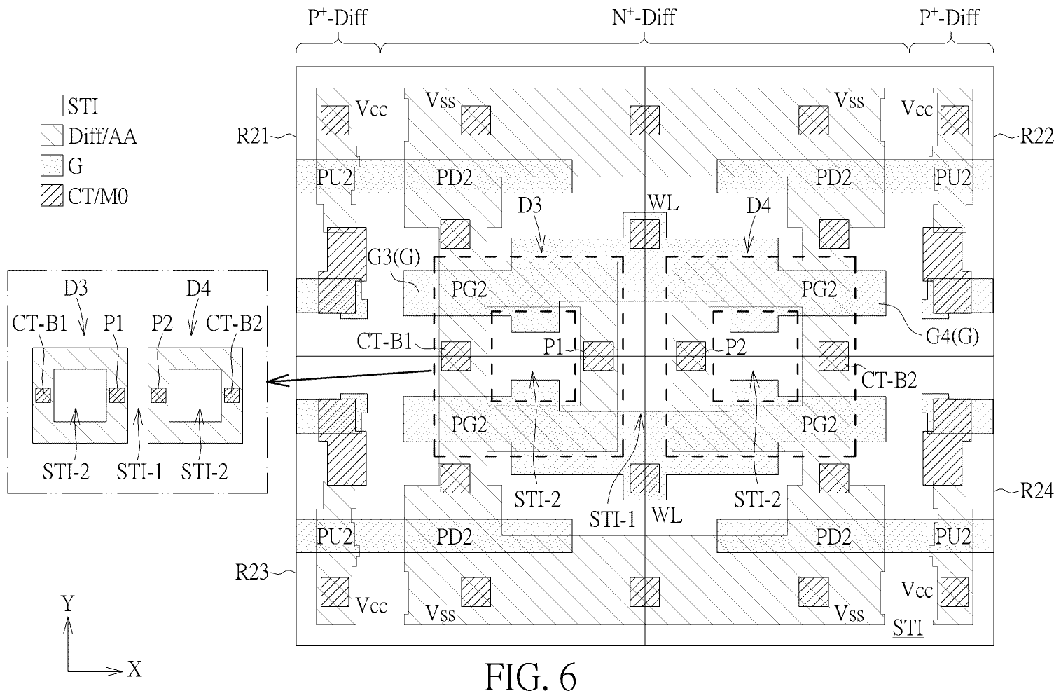

In order to reduce the leakage current of the SRAM in FIG. 5, another embodiment of the present invention is provided. Please refer to FIG. 6, which shows the layout pattern of a static random access memory (SRAM) according to a third embodiment of the present invention. As shown in FIG. 6, the layout pattern of the SRAM provided by this embodiment also includes four adjacent regions R21, R22, R23 and R24, which are adjacent to each other, and each region R21-R24 includes an SRAM cell. In order to explain the characteristics of this embodiment more clearly, only a part of the SRAM cell patterns are drawn in each region R21-R24, such as the second pull-up transistor PU2 and the second pull-down transistor PD2 and the second pass gate transistor PG2. Among them, the patterns in the regions R21 and R22 are mirrored in the vertical direction, the patterns in the regions R21 and R23 are mirrored in the horizontal direction, and the patterns in the regions R23 and R24 are mirrored in the vertical direction. In addition, reference can be made to the layout pattern shown in FIG. 2, in which the arrangement directions of the second pull-up transistor PU2, the second pull-down transistor PD2 and the second pass gate transistor PG2 in the region R21 in FIG. 6 are similar to those of the second pull-up transistor PU2, the second pull-down transistor PD2 and the second pass gate transistor PG2 in the region R shown in FIG. 2, so the positions of transistors not shown in FIG. 5 can also be known by referring to FIG. 2. It is worth noting that in FIG. 5, the first pull-up transistor PU1, the first pull-down transistor PD1 and the first pass gate transistor PG1 are located outside the indicated range, so they are not drawn. However, it can be understood that these elements should exist in the SRAM pattern, and the layout and position of these elements can be shown with reference to FIG. 2, so they will not be described in detail in this paragraph.

In this embodiment, the gate structure G of the second pass gate transistor PG2 located in the region R21 in FIG. 6 is defined as the gate structure G3, and the diffusion region Diff spanned by the gate structure G3 is defined as the diffusion region D3. In addition, the gate structure G of the second pass gate transistor PG2 located in the region R22 in FIG. 6 is defined as the gate structure G4, and the diffusion region Diff spanned by the gate structure G4 is defined as the diffusion region D4. As shown in FIG. 6, the gate structure G3 and the gate structure G4 are connected to each other and are in contact with each other, but different from FIG. 5, the diffusion regions D3 and D4 are not in contact with each other in this embodiment. In this way, the SRAM cells in the region R21 and the region R22 share the gate structures G3 and G4, and share the contact plug (labeled as contact plug CT next to WL in FIG. 6) connecting the word line WL. However, the diffusion regions are not shared, that is to say, the respective diffusion regions D3 and D4 located in the region R21 and the region R22 are separated, so two contact plugs (the pick-up contact plugs labeled P1 and P2 in FIG. 6) for releasing excess accumulated charges are respectively formed on the diffusion regions D3 and D4. In addition, in order to clearly describe the connection relationship between the elements, some elements such as bit line WL, voltage source Vss, word line BL2, etc. are directly marked next to the contact structure CT of the layout pattern.

In this embodiment, in order to clearly describe the shapes of the diffusion regions D3 and D4, enlarged patterns of the diffusion regions D3 and D4 are drawn next to the layout pattern, wherein, from the top view, the diffusion regions D3 and D4 are, for example, frame-shaped with four strip patterns, and the diffusion regions D3 and D4 are not in contact with each other, and the pick-up contact plug P1 is located on the strip pattern on the right side of the diffusion region D3, while the pick-up contact plug P2 is located on the strip pattern on the left side of the diffusion region D4.

In this embodiment, the gate structures G3 and G4 are connected to each other, and the connected gate structures G3 and G4 span the region R21 and the region R22. However, the diffusion region D3 and the diffusion region D4 are arranged separately from each other without being connected. Therefore, when the voltage is applied to the word line WL (when the word line WL is turned on), the channels under the gate structures G3 and G4 are turned on, and electrons will flow into the diffusion regions D3 and D4 under the gate structures G3 and G4. However, since the diffusion regions D3 and D4 are not connected with each other, electrons flowing into the diffusion regions D3 and D4 will not easily generate leakage current and affect the adjacent SRAM cells. In addition, in order to release the charges accumulated in the substrate in their respective regions, two pick-up contact plugs P1 and P2 are formed in this embodiment to connect the diffusion region D3 and the diffusion region D4 respectively. Compared with the above embodiments, this embodiment can significantly reduce the generation of leakage current and improve the quality of SRAM.

Based on the above description and drawings, the present invention provides a layout pattern of a static random access memory (refer to FIG. 6), which includes a first region R21 adjacent to a second region R22, a first SRAM cell located in the first region R21, a first diffusion region D3 in the first region R21. And a second SRAM cell located in the second region R22, the second region R22 contains a second diffusion region D4. A gate structure (i.e., a gate structure G3 and a gate structure G4, hereinafter defined as a gate structure G) spans the first region R21 and the second region R22, wherein the gate structure G spans the first diffusion region D3 and constitutes a first pass gate transistor PG2 of the first SRAM cell. The gate structure spans the second diffusion region D4 and constitutes a second pass gate transistor PG2 of the second SRAM cell, wherein the gate structure G extends along a first direction (X direction), and the first diffusion region D3 overlapping with the gate structure G and the second diffusion region D4 overlapping with the gate structure G are not connected in the first direction (as shown in FIG. 6, the first diffusion region D3 and the second diffusion region D4 are separated from each other in the X direction).

In some embodiments of the present invention, when viewed from a top view, the first diffusion region D3 and the second diffusion region D4 are frame-shape patterns (as shown in FIG. 6).

In some embodiments of the present invention, the first diffusion region D3 and the second diffusion region D4 are arranged along the first direction (X direction) when viewed from the top, and a first shallow trench isolation STI-1 is further included between the first diffusion region D3 and the second diffusion region D4 (as shown in FIG. 6, that is, the shallow trench isolation STI-1 between the first diffusion region D3 and the second diffusion region D4 is defined here).

In some embodiments of the present invention, the gate structure G overlaps with the first diffusion region D3, the second diffusion region D4 and the first shallow trench isolation STI-1 when viewed from the top.

In some embodiments of the present invention, it further includes a first bit line contact structure CT-B1 located on the first diffusion region D3 and electrically connected to a bit line (bit line BL2 located in the region R21), and a second bit line contact structure CT-B2 located on the second diffusion region D4 and electrically connected to another bit line (bit line BL2 located in the region R22).

In some embodiments of the present invention, it further includes a first pick-up contact plug P1 located on the first diffusion region D3, and a second pick-up contact plug P2 located on the second diffusion region D4.

In some embodiments of the present invention, the first diffusion region D3 presents a frame shape and includes four sides, wherein the first bit line contact CT-B1 is located on one side of the first diffusion region D3, and the first pick-up contact plug P1 is located on the other side of the first diffusion region D3.

In some embodiments of the present invention, the first bit line contact structure CT-B1 and the second bit line contact structure CT-B2 are symmetrically arranged with each other, and the first pick-up contact plug P1 and the second pick-up contact plug P2 are symmetrically arranged with each other.

In some embodiments of the present invention, the first diffusion region D3 presents a frame shape, and further comprises a second shallow trench isolation STI-2 located in the frame-shaped first diffusion region D3 and surrounded by the first diffusion region D3.

In some embodiments of the present invention, a word line contact (the contact plug CT connecting the word line WL in FIG. 6) is further included to electrically connect the gate structure G, wherein the word line contact is electrically connected with a word line WL.

The invention also provides a manufacturing method of layout pattern of static random access memory, which includes defining a first region R21 adjacent to a second region R22, forming a first SRAM cell in the first region R21, and forming a second SRAM cell in the second region R22. The second region R22 contains a second diffusion region D4, forming a gate structure (i.e., a gate structure G3 and a gate structure G4, hereinafter defined as a gate structure G) spanning the first region R21 and the second region R22, wherein the gate structure G spans the first diffusion region D3 and constitutes a first pass gate transistor PG2 of the first SRAM cell. The gate structure spans the second diffusion region D4 and constitutes a second pass gate transistor PG2 of the second SRAM cell, wherein the gate structure G extends along a first direction (X direction), and the first diffusion region D3 overlapping with the gate structure G and the second diffusion region D4 overlapping with the gate structure G are not connected in the first direction (as shown in FIG. 6, the first diffusion region D3 and the second diffusion region D4 are separated from each other in the X direction).

In some embodiments of the present invention, when viewed from a top view, the first diffusion region D3 and the second diffusion region D4 are frame-shape patterns (as shown in FIG. 6).

In some embodiments of the present invention, the first diffusion region D3 and the second diffusion region D4 are arranged along the first direction (X direction) when viewed from the top, and a first shallow trench isolation STI-1 is formed between the first diffusion region D3 and the second diffusion region D4 (as shown in FIG. 6, that is, shallow trench isolation STI between the first diffusion region D3 and the second diffusion region D4, which is defined as shallow trench isolation STI-1 here).

In some embodiments of the present invention, the gate structure G overlaps with the first diffusion region D3, the second diffusion region D4 and the first shallow trench isolation STI-1 when viewed from the top.

In some embodiments of the present invention, a first bit line contact structure CT-B1 is formed on the first diffusion region D3 and electrically connected to a bit line (bit line BL2 in region R21), and a second bit line contact structure CT-B2 is formed on the second diffusion region D4 and electrically connected to another bit line (bit line BL2 in region R22).

In some embodiments of the present invention, a first pick-up contact plug P1 is formed on the first diffusion region D3, and a second pick-up contact plug P2 is formed on the second diffusion region D4.

In some embodiments of the present invention, the first diffusion region D3 presents a frame shape and includes four sides, wherein the first bit line contact CT-B1 is located on one side of the first diffusion region D3, and the first pick-up contact plug P1 is located on the other side of the first diffusion region D3.

In some embodiments of the present invention, the first bit line contact structure CT-B1 and the second bit line contact structure CT-B2 are symmetrically arranged with each other, and the first pick-up contact plug P1 and the second pick-up contact plug P2 are symmetrically arranged with each other.

In some embodiments of the present invention, the first diffusion region D3 presents a frame shape, and further comprises a second shallow trench isolation STI-2 formed in the frame-shaped first diffusion region D3 and surrounded by the first diffusion region D3.

In some embodiments of the present invention, a word line contact (contact plug CT connecting the word line WL in FIG. 6) is formed to electrically connect the gate structure G, wherein the word line contact is electrically connected with a word line WL.

To sum up, the present invention discloses a layout pattern of 6T-SRAM. When a plurality of SRAM cells are arranged adjacent to each other, some components may be shared, but at the same time, larger leakage current may be generated. The invention is characterized in that the diffusion region of the second pass gate transistor in the first region and the diffusion region of the second pass gate transistor in the adjacent second region are designed to be separated from each other, but the gate structure of the second pass gate transistor in the first region and the gate structure of the second pass gate transistor in the adjacent second region are still in contact with each other. When the word line is turned on, electrons will flow into the diffusion region below the gate structure, but since the diffusion regions below the gate structure are not connected with each other, so the leakage current between the two regions can be effectively isolated, and the quality of the SRAM can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout pattern of a static random access memory, comprising:
a first region and a second region, wherein the first region and the second region are adjacent to each other;
a first SRAM cell located in the first region, which contains a first diffusion region;
a second SRAM cell located in the second region, which contains a second diffusion region;
a gate structure spanning the first region and the second region, wherein the gate structure spans the first diffusion region and constitutes a first pass gate transistor of the first SRAM cell, and the gate structure spans the second diffusion region and constitutes a second pass gate transistor of the second SRAM cell, wherein the gate structure extends along a first direction, and the first diffusion region overlapping with the gate structure and the second diffusion region overlapping with the gate structure are not connected in the first direction.

2. The layout pattern of the SRAM according to claim 1, wherein the first diffusion region and the second diffusion region are frame-shape patterns when viewed from a top view.

3. The layout pattern of the SRAM according to claim 2, wherein the first diffusion region and the second diffusion region are arranged along the first direction when viewed from the top view, and further comprises a first shallow trench isolation between the first diffusion region and the second diffusion region.

4. The layout pattern of the SRAM according to claim 3, wherein the gate structure overlaps with the first diffusion region, the second diffusion region and the first shallow trench isolation from the top view.

5. The layout pattern of the SRAM according to claim 2, further comprising a first bit line contact structure located on the first diffusion region and electrically connected to a bit line, and a second bit line contact structure located on the second diffusion region and electrically connected to another bit line.

6. The layout pattern of the SRAM according to claim 5, further comprising a first pick-up contact plug located on the first diffusion region and a second pick-up contact plug located on the second diffusion region.

7. The layout pattern of the SRAM according to claim 6, wherein the first diffusion region presents a frame shape and includes four sides, wherein the first bit line contact is located on one side of the first diffusion region and the first pick-up contact plug is located on the other side of the first diffusion region.

8. The layout pattern of SRAM according to claim 6, wherein the first bit line contact structure and the second bit line contact structure are symmetrically arranged, and the first pick-up contact plug and the second pick-up contact plug are symmetrically arranged.

9. The layout pattern of the SRAM according to claim 2, wherein the first diffusion region presents a frame shape, and further comprises a second shallow trench isolation located in and surrounded by the frame-shaped first diffusion region.

10. The layout pattern of the SRAM according to claim 1, further comprising a word line contact electrically connected to the gate structure, wherein the word line contact is electrically connected to a word line.

11. A method for manufacturing a layout pattern of a static random access memory, comprising:
defining a first region adjacent to a second region;
forming a first SRAM cell in the first region, wherein the first region contains a first diffusion region;
forming a second SRAM cell in the second region, and the second region contains a second diffusion region;
forming a gate structure spanning the first region and the second region, wherein the gate structure spans the first diffusion region and constitutes a first pass gate transistor of the first SRAM cell, and the gate structure spans the second diffusion region and constitutes a second pass gate transistor of the second SRAM cell, wherein the gate structure extends along a first direction, and the first diffusion region overlapping with the gate structure and the second diffusion region overlapping with the gate structure are not connected in the first direction.

12. The method for manufacturing the layout pattern of the SRAM according to claim 11, wherein the first diffusion region and the second diffusion region are frame-shape patterns when viewed from a top view.

13. The method for manufacturing the layout pattern of SRAM according to claim 12, wherein the first diffusion region and the second diffusion region are arranged along the first direction when viewed from the top view, and further comprises a first shallow trench isolation between the first diffusion region and the second diffusion region.

14. The manufacturing method of the layout pattern of the SRAM according to claim 13, wherein the gate structure overlaps with the first diffusion region, the second diffusion region and the first shallow trench isolation from the top view.

15. The method for manufacturing the layout pattern of SRAM according to claim 12, further comprising forming a first bit line contact structure located on the first diffusion region and electrically connected to a bit line, and forming a second bit line contact structure located on the second diffusion region and electrically connected to another bit line.

16. The method for manufacturing the layout pattern of SRAM according to claim 15, further comprising forming a first pick-up contact plug on the first diffusion region and forming a second pick-up contact plug on the second diffusion region.

17. The method for manufacturing the layout pattern of the SRAM according to claim 16, wherein the first diffusion region presents a frame shape and includes four sides, wherein the first bit line contact is located on one side of the first diffusion region and the first pick-up contact plug is located on the other side of the first diffusion region.

18. The method for manufacturing the layout pattern of the SRAM according to claim 16, wherein the first bit line contact structure and the second bit line contact structure are symmetrically arranged, and the first pick-up contact plug and the second pick-up contact plug are symmetrically arranged.

19. The method for manufacturing the layout pattern of the SRAM according to claim 12, wherein the first diffusion region presents a frame shape, and further comprises a second shallow trench isolation located in and surrounded by the frame-shaped first diffusion region.

20. The method for manufacturing the layout pattern of the SRAM according to claim 11, further comprising forming a word line contact electrically connected to the gate structure, wherein the word line contact is electrically connected to a word line.
